(19) United States
(12) Patent Application Publication
(10) Pub. No.: US 2011/0006378 A1
(43) Pub. Date: Jan. 13, 2011

(54) Semiconductor Manufacturing Method Using Maskless Capping Layer Removal

(75) Inventors: Muhammad Hussain, Austin, TX (US); Chang Seo Park, Austin, TX (US)

Correspondence Address: FULBRIGHT & JAWORSKI L.L.P., 600 CONGRESS AVE., SUITE 2400, AUSTIN, TX, 78701, US

(73) Assignee: SEMATECH, INC.

(21) Appl. No.: 12/498,775

(22) Filed: Jul. 7, 2009

(51) Int. Cl. H01L 29/78; H01L 21/3205; H01L 21/311

(52) U.S. Cl. 257/392; 438/584; 438/703; 257/E29.255; 257/E21.249; 257/E21.294

(57) ABSTRACT

A method of manufacturing a semiconductor device includes depositing a first capping layer on a dielectric layer. The method also includes etching the first capping layer from a second portion of the semiconductor device. The first capping layer remaining in a first portion of the semiconductor device may form a PMOS device. The method further includes depositing a second capping layer after etching the first capping layer. After the second capping layer is deposited a maskless process results in selectively etching the second capping layer from the first portion of the semiconductor device. The second portion of the semiconductor device may be a NMOS device. The method described may be used in manufacturing integrated CMOS devices as scaling reduces device size. Additionally, the method of selectively etching capping layers may be used to manufacture multi-threshold voltage devices.

### TECHNICAL FIELD

The present disclosure generally relates to semiconductor devices. More specifically, the present disclosure relates to manufacturing semiconductor devices.

### BACKGROUND

Integrated circuits (ICs) are combinations of transistors and other components fabricated on wafers. Commonly, these wafers are semiconductor materials, and, in particular, silicon. Recently, transistors sizes have reduced in size to 45 nm and are continuing to shrink to 32 nm. The semiconductor industry remains focused on further reducing transistor size, however new challenges arrive with each size reduction.

Complementary metal-oxide-semiconductor (CMOS) devices combine coupled n-channel MOS (NMOS) and p-channel MOS (PMOS) transistors. One challenge in constructing CMOS devices is manufacturing two transistors in parallel processing on a single semiconductor wafer. Often the PMOS and NMOS structures have different materials. For example, a PMOS device may have a first material as a capping layer while an NMOS device may have a different material as a capping layer.

As sizes shrink, integrating the NMOS and PMOS processing to manufacture CMOS devices increases in complexity. Conventional etching processes during semiconductor manufacturing may lead to degraded electrical properties in NMOS and PMOS devices. Changes in electrical properties are magnified as devices reduce size.

One proposed solution uses HF:HCl chemistry for etching capping layers in CMOS devices. HF:HCl chemistry results in damage to shallow trench isolation and loss of interfacial dielectric on the CMOS device. Additional proposed solutions include isolating individual metal gates in CMOS devices. Conventionally this uses reverse lithography, which adds lithography processes resulting in additional cost and challenges with overlay. Alternatively, replacement-gate or gate-last manufacturing processes have been proposed, which has limited scalability to smaller transistor sizes.

### SUMMARY OF THE INVENTION

According to one aspect of the disclosure, a method of manufacturing a semiconductor device includes depositing a first capping layer on a substrate. The method may also include depositing a first hard mask layer on the first capping layer. The method may further includes patterning the first hard mask layer to a first plurality of regions of the substrate. The method may also include depositing a second capping layer on the substrate after patterning the first hard mask layer. The method may further include selectively etching the second capping layer from the first plurality of region of the substrate.

According to another aspect of the disclosure, a method of manufacturing a semiconductor device may include depositing a hard mask layer on a dielectric layer. The method may also include patterning the hard mask layer to a first plurality of regions of the dielectric layer. The method may further include depositing a first capping layer on the dielectric layer after patterning the hard mask layer. The method may also include selectively etching the first capping layer from the first plurality of regions of the dielectric layer. The method may further include depositing a second hard mask after selectively etching the first capping layer. The method may also include patterning the second hard mask layer to a second plurality of regions of the dielectric layer. In one embodiment, the method further includes depositing a second capping layer after patterning the second hard mask layer. The method may also include selectively etching the second capping layer from the second plurality of regions of the dielectric layer.

According to yet another aspect of the disclosure, a semiconductor device may include a first dielectric layer. The semiconductor device may also include a second dielectric layer contacting the first dielectric layer. The semiconductor device may have at least a first region and a second region, a composition of the first dielectric layer and the second dielectric layer differing in the first region and the second region.

The foregoing has outlined rather broadly the features and technical advantages of the present disclosure in order that the detailed description that follows may be better understood. Additional features and advantages will be described hereinafter which form the subject of the claims of the disclosure. It should be appreciated by those skilled in the art that the conception and specific embodiments disclosed may be readily utilized as a basis for modifying or designing other structures for carrying out the same purposes of the present disclosure. It should also be realized by those skilled in the art that such equivalent constructions do not depart from the technology of the disclosure as set forth in the appended claims. The novel features which are believed to be characteristic of the disclosure, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is a flow chart illustrating a process for manufacturing a semiconductor device according to one embodiment.

FIG. 2A is a cross-sectional view illustrating a semiconductor device stack according to one embodiment.

FIG. 2B is a cross-sectional view illustrating a semiconductor device stack after patterning a first hard mask according to one embodiment.

FIG. 2C is a cross-sectional view illustrating a semiconductor device after patterning a second hard mask according to one embodiment.

FIG. 2D is a cross-sectional view illustrating a semiconductor device after patterning a first capping layer according to one embodiment.

FIG. 2E is a cross-sectional view illustrating a semiconductor device after depositing a second capping layer according to one embodiment.

FIG. 2F is a cross-sectional view illustrating a semiconductor device after selectively etching a second capping layer according to one embodiment.

FIG. 2G is a cross-sectional view illustrating a semiconductor device after removing the second hard mask according to one embodiment.

FIG. 2H is a cross-sectional view illustrating a semiconductor device after depositing a conducting layer according to one embodiment.

FIG. 3 is a flow chart illustrating a process for manufacturing a semiconductor device having multiple threshold voltages according to one embodiment.

FIG. 4A is a cross-sectional view illustrating a semiconductor device stack having multiple threshold voltages according to one embodiment.

FIG. 4B is a cross-sectional view illustrating a semiconductor device stack having multiple threshold voltages after selectively etching the first capping layer according to one embodiment.

FIG. 4C is a cross-sectional view illustrating a semiconductor device stack having multiple threshold voltages after depositing a second capping layer according to one embodiment.

FIG. 4D is a cross-sectional view illustrating a semiconductor device stack having multiple threshold voltages after selectively etching a second capping layer according to one embodiment.

FIG. 4E is a cross-sectional view illustrating a semiconductor device stack having multiple threshold voltages after depositing a conducting layer according to one embodiment.

FIG. 5 is a block diagram illustrating an electronic device in which a semiconductor device is integrated according to one embodiment.

### DETAILED DESCRIPTION

The semiconductor manufacturing process discussed below uses selective etching to remove a capping layer from one region of a CMOS device without affecting a second region of a CMOS device. For example, a lanthanum oxide capping layer may be selectively etched from a PMOS region of a CMOS device without use of an additional mask. According to one embodiment, selective etching occurs based on the materials under the capping layer when an etching solution is applied to the capping layer.

Maskless manufacturing of CMOS devices as described below eases integration issues as feature sizes reduce. Additionally, integration complexity and cost effectiveness improve by eliminating reverse lithography. During maskless manufacturing loss of shallow trench isolation (STI) and interfacial oxide is reduced because non-HF chemistry etches the capping layer.

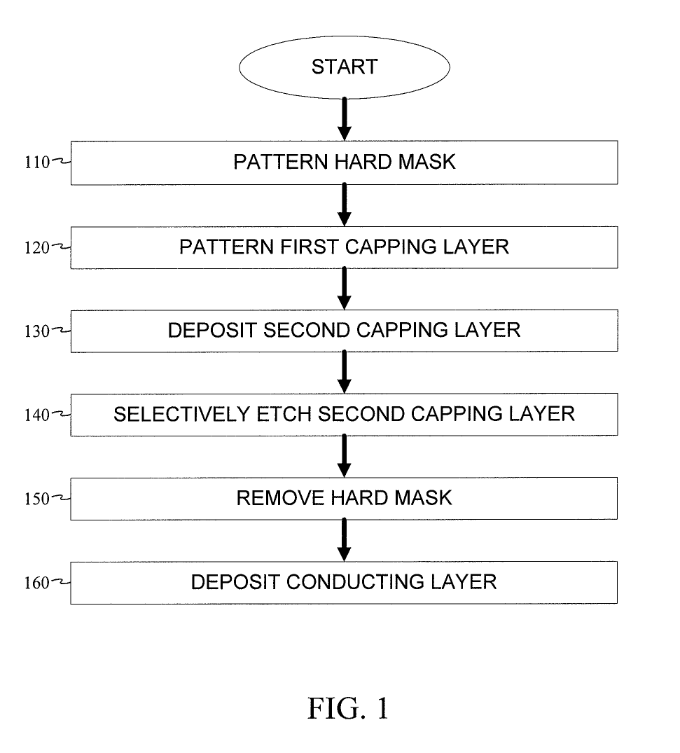

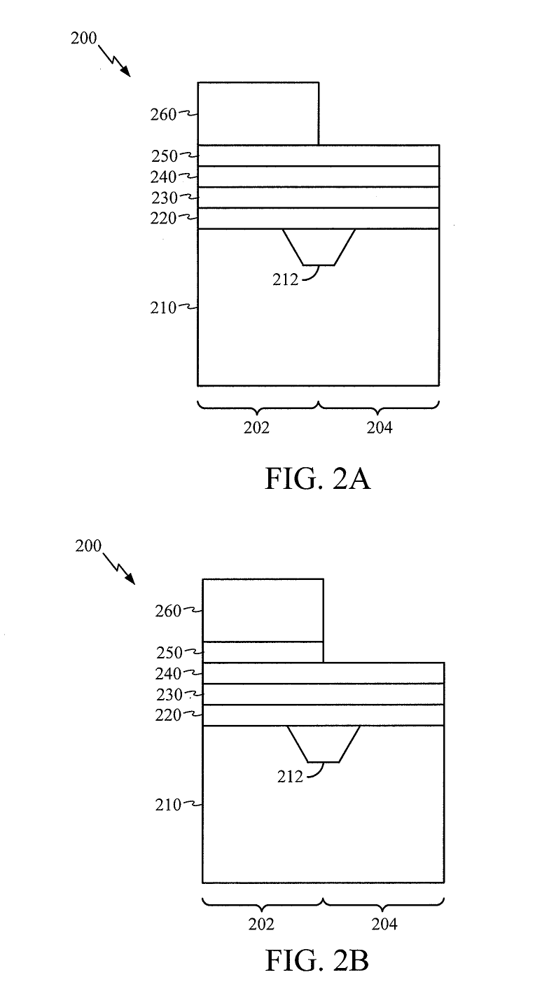

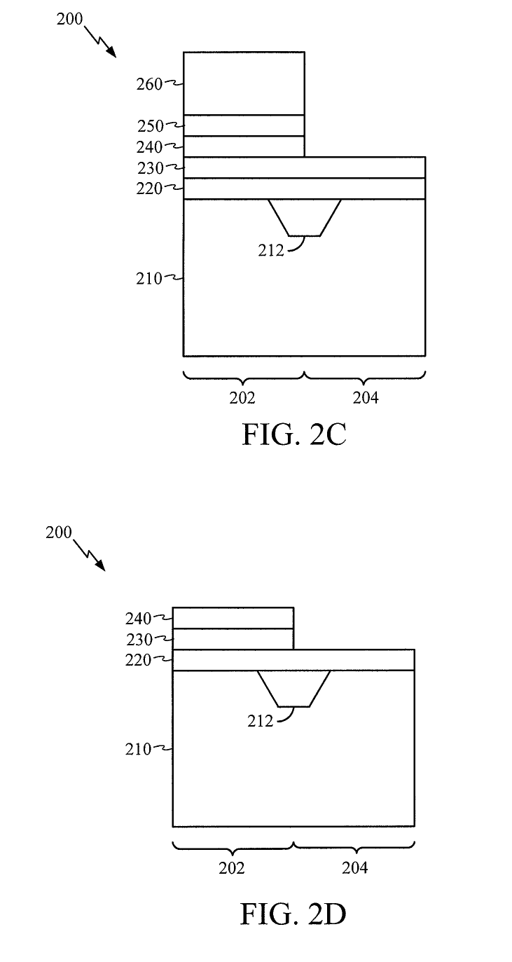

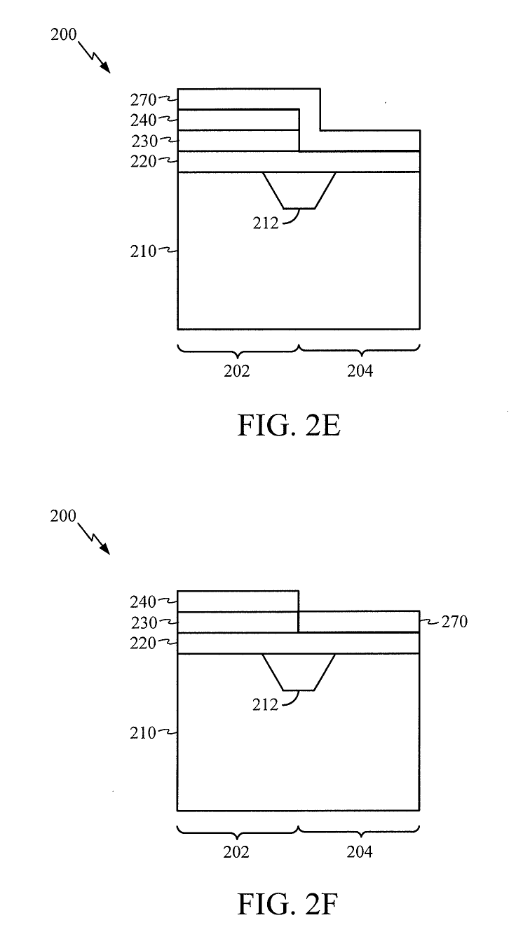

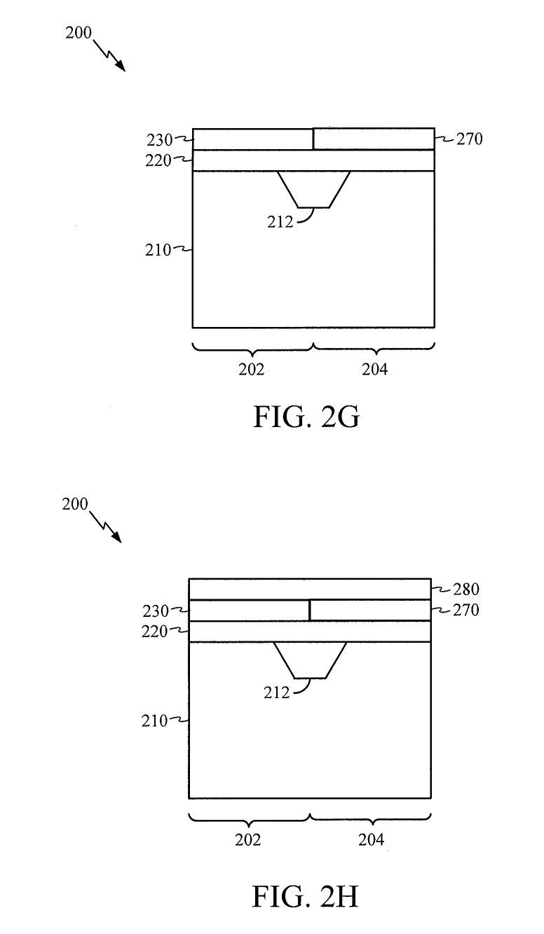

FIG. 1 is a flow chart illustrating a process for manufacturing a semiconductor device according to one embodiment, and will be discussed along with FIGS. 2A-2H. FIGS. 2A-2H are cross-sectional views illustrating manufacturing a semiconductor device.

FIG. 2A is a cross-sectional view illustrating a semiconductor device stack according to one embodiment. A device stack 200 includes a semiconductor substrate 210 having a shallow trench isolation (STI) 212. The STI 212 separates the semiconductor substrate 210 into regions 202, 204. Each of the regions 202, 204 may represent several locations on the substrate 210. According to one embodiment, the regions 202, 204 may correspond to an PMOS and a NMOS region, respectively. A dielectric layer 220 may be deposited on the semiconductor substrate 210. The dielectric layer 220 may be, for example, silicon oxide or a high-K dielectric such as hafnium oxide. Above the dielectric layer 220 may be a capping layer 230. The capping layer 230 may be an interfacial layer such as aluminum oxide (AlOₓ) or lanthanum oxide (LaOₓ).

According to one embodiment, the capping layer 230 is aluminum oxide in a PMOS-first integration process as described below. According to another embodiment, the capping layer 230 may be lanthanum oxide in a NMOS-first integration process. In yet another embodiment, the capping layer 230 may be absent from the device stack 200. In this embodiment, either PMOS or NMOS transistors may be manufactured using the processes described below.

A hard mask 240 and a hard mask 250 may be deposited on the capping layer 230. The hard mask 240 and the hard mask 250 may be selected, in part, to obtain desirable etching selectivity in later processing between the hard masks 240, 250 and the capping layer 230. Additional factors in determining hard masks may include protecting layers in the device stack 200 from damage during processing, such as plasma damage. The hard masks 240, 250 may be, for example, amorphous silicon and titanium nitride, respectively. Although two hard masks are illustrated, a process as described below may be adapted for use with additional or fewer hard mask layers.

A photoresist 260 may be deposited on the hard mask 250 and patterned. The pattern of the photoresist 260 may determine the size and shape of the devices having the capping layer 230 as an interfacial layer. That is, in a PMOS-first integration process, the PMOS devices may have a shape and size determined, in part, by the photoresist 260. According to one embodiment, the photoresist 260 may be patterned in shape and size to substantially match the region 202.

At a block 110 hard masks are patterned. A number of hard masks used for transferring patterns to device layers below the hard masks may be determined, in part, by the materials of the hard mask layers and the device layers and the etch process chemistry. FIG. 2B is a cross-sectional view illustrating a semiconductor device stack after patterning a first hard mask according to one embodiment. The pattern in the photoresist 260 is transferred to the hard mask 250. In the embodiment having titanium nitride as the hard mask 250, a dry etch using a mixture of Ar/Cl₂ may be used to pattern the hard mask 250.

Following etch of the hard mask 250, a cleaning process may strip the photoresist 260 and clean the exposed surfaces of the device stack 200. The photoresist 260 may be stripped with an NH₃ ashing process. In the embodiment having titanium nitride for the hard mask 250, an ashing process with no oxygen protects the titanium nitride from oxidization. Oxidation of the titanium nitride may slow etch processing. According to another embodiment, the device stack 200 may be cleaned with N-methyl pyrrolidone (NMP).

FIG. 2C is a cross-sectional view illustrating a semiconductor device after patterning a second hard mask according to one embodiment. The hard mask 240 is patterned to have substantially similar size and shape to the patterned hard mask 250 above the hard mask 240. In the embodiment having titanium nitride for the hard mask 250 and amorphous silicon for the hard mask 240, a wet etch having a combination of hydrofluoric acid (HF) and ammonium hydroxide (NH₄OH) etches the hard mask 240.

At a block 120 the first capping layer is patterned. The block 120 may be optional depending, in part, on the presence of the capping layer 230. FIG. 2D is a cross-sectional view illustrating a semiconductor device after patterning a first capping layer according to one embodiment. The pattern of the hard mask 240 is transferred to the capping layer 230. In the embodiment having amorphous silicon for the hard mask 240 and aluminum oxide for the capping layer 230, a SC1 mixture may etch the capping layer 230 and strip the hard mask 250. An SC1 mixture includes de-ionized water, hydrogen peroxide (H₂O₂), and ammonium hydroxide (NH₄OH).

At a block 130 the second capping layer is deposited. FIG. 2E is a cross-sectional view illustrating a semiconductor device after depositing a second capping layer according to one embodiment. A capping layer 270 is deposited on the device stack 200. In the PMOS-first integration process the capping layer 270 may be lanthanum oxide or another interfacial layer may be used for an NMOS device. The capping layer 270 may also be exposed to a nitrogen plasma after deposition to further decrease any etching of the capping layer 270 in later processing.

At a block 140 the second capping layer is selectively etched using a maskless process. FIG. 2F is a cross-sectional view illustrating a semiconductor device after selectively etching a second capping layer according to one embodiment. Selectively etching the capping layer 270 results in removal of the capping layer 270 from the region 202 but leaves the capping layer 270 substantially unaltered in the region 204. An etching solution may slowly etch a portion of the capping layer 270 that is in contact with the dielectric layer 220 and quickly etch the capping layer 270 in contact with the hard mask 240. In the embodiment having lanthanum oxide for the capping layer 270, an SC1 solution may be used to selectively etch the capping layer 270.

At a block 150 the hard mask layers are removed. FIG. 2G is a cross-sectional view illustrating a semiconductor device after removing the second hard mask according to one embodiment. The hard mask 240 may be removed after selectively etching the capping layer 270. In the embodiment having amorphous silicon for the hard mask 240, ammonium hydroxide (NH₄OH) may etch the hard mask 240.

At a block 160 a single conducting layer is deposited. The block 160 may be optional, depending in part, on a contact structure for the device stack 200. FIG. 2H is a cross-sectional view illustrating a semiconductor device after depositing a conducting layer according to one embodiment. A conducting layer 280 may be deposited on the device stack 200. According to one embodiment, the conducting layer 280 may be a gate electrode and include a metal or metal nitride such as, titanium silicon nitride (TiSiN).

The device stack 200 of FIG. 2H may be further processed to manufacture isolation layers and electrical paths that couple to the conducting layer 280. For example, the device stack 200 may be an integrated CMOS device having a PMOS device in the region 202 and a NMOS device in the region 204. Producing different devices in the regions 202, 204 using the process described above increases scalability due, in part, to the maskless approach for selective etching. Additionally, damage to the dielectric layer 220 and the STI 212 is reduced by selective etching. Thus, defects in devices in the regions 202, 204 are reduced allowing scaling of device size in the regions 202, 204 with little or no degradation of electrical properties.

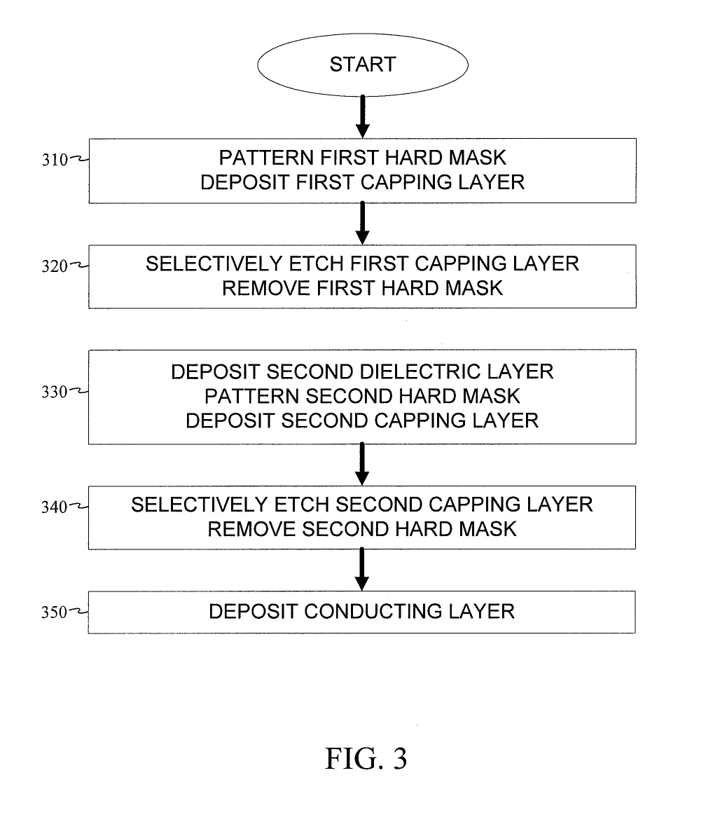

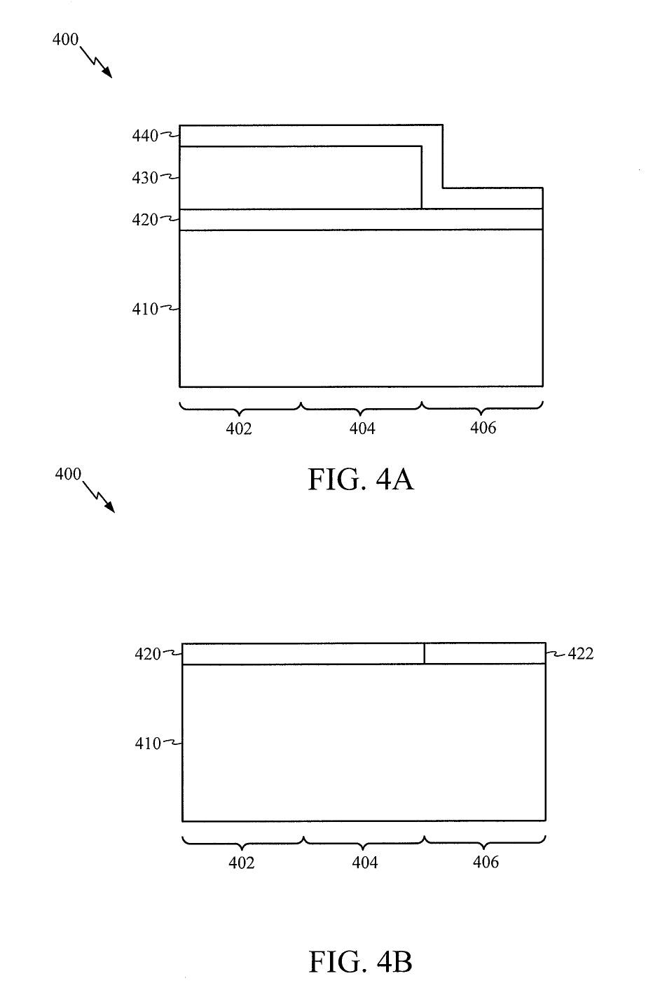

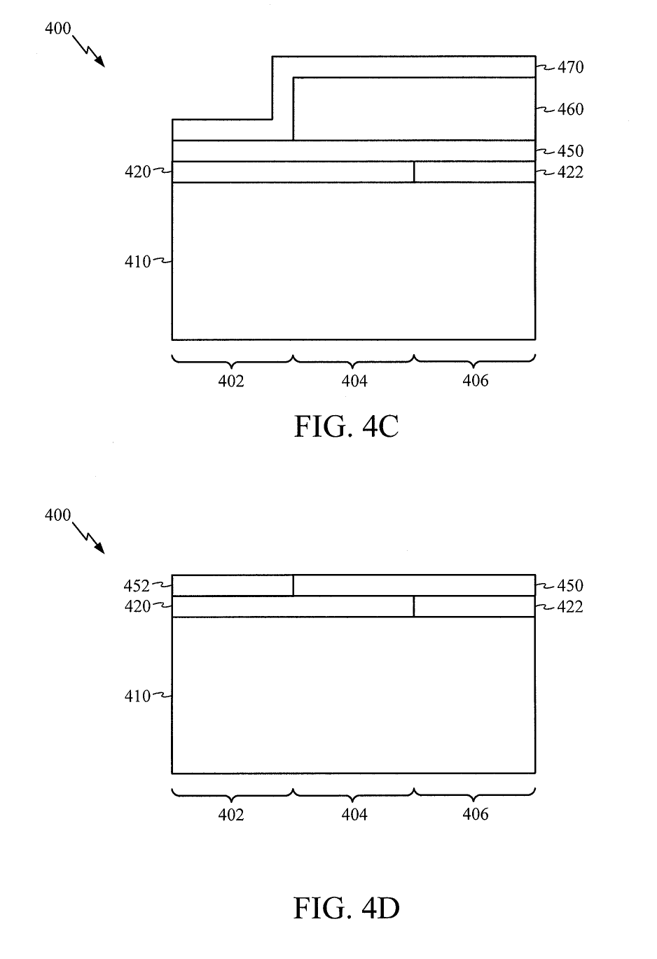

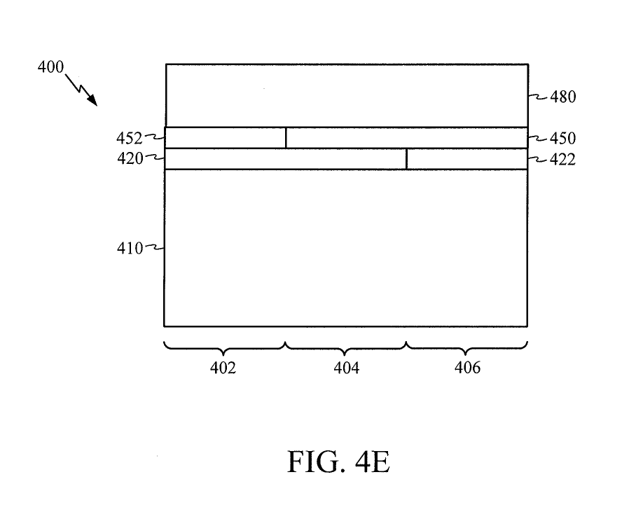

Semiconductor devices having multiple threshold voltages may be manufactured through the process described above. FIG. 3 is a flow chart illustrating a process for manufacturing a semiconductor device having multiple threshold voltages according to one embodiment, and will be discussed along with FIGS. 4A-4E. FIGS. 4A-4E are cross-sectional views illustrating a semiconductor device stack having multiple threshold voltages.

At block 310, a first hard mask is patterned followed by deposition of a first capping layer. FIG. 4A is a cross-sectional view illustrating a semiconductor device stack having multiple threshold voltages according to one embodiment. A device stack 400 includes a semiconductor substrate 410 having regions 402, 404, and 406. On the semiconductor substrate 410 is a dielectric layer 420 such as, for example, a high-K dielectric. A first hard mask 430 is deposited on the dielectric layer 420 and patterned. The shape and size of the patterned hard mask 430 determine, in part, the shape and size of the region 406. Material for the hard mask 430 may be selected, in part, based on material in the capping layer 440 and the chemical used for selective etching later in semiconductor processing.

According to one embodiment, the dielectric layer 420 may be haffiium oxide, and the capping layer 440 may be lanthanum oxide. In this embodiment, the hard mask 430 may be amorphous silicon, which provides selectivity during selective etching later in semiconductor processing.

At block 320, the first capping layer is selectively etched from the first hard mask and the first hard mask is removed. FIG. 4B is a cross-sectional view illustrating a semiconductor device stack having multiple threshold voltages after selectively etching the first capping layer according to one embodiment. An annealing process of heating and cooling the device stack 400 is performed to diffuse the capping layer 440 with the dielectric layer 420 to form a composite dielectric 422 in the region 406. Selective etching of the capping layer 440 results in removal of the capping layer 440 from the regions 402, 404 where the capping layer 440 contacts the hard mask 430. The composite dielectric 422 remains substantially unaltered in the region 406 by the selective etching. After selective etching, the hard mask 430 is removed from the device stack 400.

In the embodiment having lanthanum oxide for the capping layer 440 and amorphous silicon for the hard mask 430, an SC1 solution may be used for selectively etching the capping layer 440. The SC1 solution may etch the capping layer 440 faster in the regions 402, 404 in which the capping layer 440 contacts the hard mask 430 than the composite dielectric 422 in the region 406.

At block 330, a second dielectric layer is deposited followed by a second hard mask. The second hard mask is patterned and a second capping layer is deposited. FIG. 4C is a cross-sectional view illustrating a semiconductor device stack having multiple threshold voltages after depositing a second capping layer according to one embodiment. A second dielectric layer 450 is deposited on the device stack 400 followed by a second hard mask 460, which is deposited and patterned. The shape and size of the hard mask 460 after patterning determines, in part, the shape and size of the region 402. A second capping layer 470 is deposited on the device stack 400.

The capping layer 470 may or may not be the same material as the capping layer 440. According to one embodiment, the capping layer 470 may be lanthanum oxide, the hard mask 460 may be amorphous silicon, and the dielectric layer 450 may be a high-K dielectric. Selection of material for the dielectric layer 450 and the capping layer 470 may be based, in part, on a desired threshold voltage for the regions 402, and 404.

At block 340, the second capping layer is selectively etched from the second hard mask followed by removal of the second hard mask. FIG. 4D is a cross-sectional view illustrating a semiconductor device stack having multiple threshold voltages after selectively etching a second capping layer according to one embodiment. An annealing process of heating and cooling the device stack 400 is performed to diffuse the capping layer 470 with the dielectric layer 450 to form a composite dielectric 452. Selective etching results in removal of the capping layer 470 where the capping layer 470 is in contact with the hard mask 460 in the regions 404, 406. The composite dielectric 452 experiences little or no etching during the selective etch. The hard mask 460 is removed from the device stack 400 after selective etching of the capping layer 470.

As a result of the selective etching processes as described above, the device stack 400 has different materials in the regions 402, 404, and 406 resulting in different threshold voltages for the regions 402, 404, and 406. For example, the region 402 has a semiconductor substrate followed by a dielectric layer, and a composite dielectric layer. The region 406 has a semiconductor substrate followed by a composite dielectric layer and a dielectric layer. The region 404 has a semiconductor substrate followed by two dielectric layers. The different materials in the regions 402, 404, and 406 may result in devices having different threshold voltages.

According to an embodiment having lanthanum oxide as the capping layers 440, 470 and hafnium oxide as the dielectric layers 420, 450, the region 404 has a higher threshold voltage than the regions 402, 406. In this embodiment, the region 406 has a lower threshold voltage than the regions 402, 404.

At block 350, a conducting layer is deposited on the device stack. FIG. 4E is a cross-sectional view illustrating a semiconductor device stack having multiple threshold voltages after depositing a conducting layer according to one embodiment. A conducting layer 480 is deposited on the device stack 400. The conducting layer 480 may be a gate electrode and include a metal or metal nitride.

The threshold voltage of the device stack 400 in the regions 402, 404, and 406 may be different based, in part, on the materials in the dielectric layers 420, 450, the capping layers 440, 470, and the duration and temperature of the annealing processes. The threshold voltage may also be varied through the thicknesses and the materials parameters of the layers 420, 450, 440, and 470. For example, time, background pressure, and power may be varied during deposition of the layers 420, 450, 440, and 470 to achieve different thicknesses or properties. Additionally, parameters of the annealing processes may affect the composition of the composite dielectrics 422, 452. Although only three regions are shown in the device stack 400, many more regions may be manufactured through similar processes.

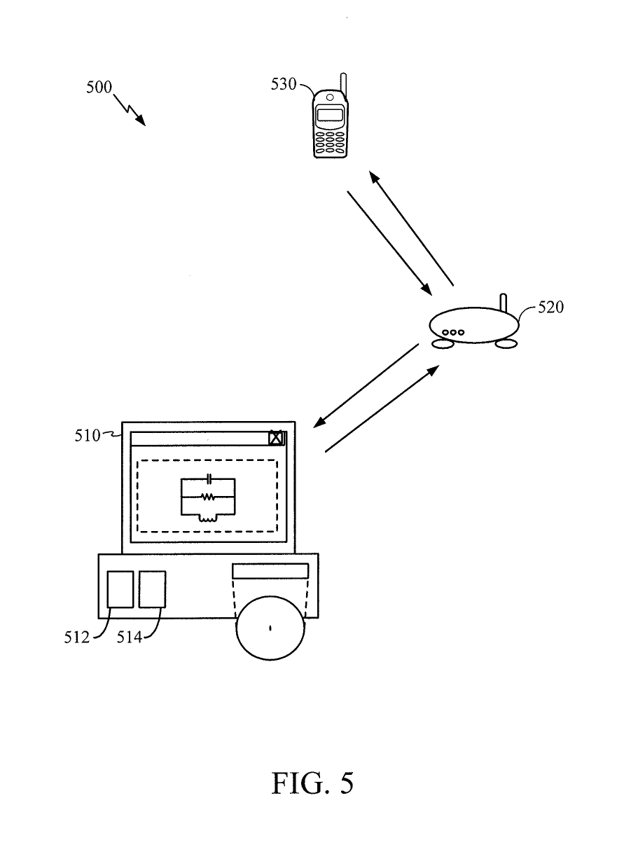

A semiconductor device manufactured by the processes described above may be integrated into electronic devices. FIG. 5 is a block diagram illustrating an electronic device in which a semiconductor device is integrated according to one embodiment. A network 500 includes a gateway 520 and devices 510, 530. One device may be a computer 510 having a processor 512 and memory 514 including semiconductor parts manufactured by the processes described above. Another device may be a mobile phone 530, which may also include a processor and memory (not shown) manufactured by the processes described above. Other devices such as global positioning system (GPS) devices, personal digital assistants (PDAs), music players, or set-top blocks may include a processor, memory, or other semiconductor component manufactured by the process described above.

The semiconductor manufacturing process described above allows maskless selective removal of a capping layer in a semiconductor device. According to one embodiment, the process manufactures PMOS and NMOS devices by selectively removing the capping layer from one region of a CMOS device. For example, lanthanum oxide may be selectively removed from a PMOS region but remains substantially unaltered in an NMOS region. The PMOS and NMOS regions have little or no modification of their electrical properties after selective etching. Controlling the etch process eliminates gate loss, which may happen with other etching techniques. Further the process is scalable to nodes below 32 nm as a result of the maskless technique.

Although the present disclosure and its advantages have been described in detail, it should be understood that various changes, substitutions and alterations can be made herein without departing from the technology of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. A method of manufacturing a semiconductor device, the method comprising:
depositing a first capping layer on a substrate;
depositing a first hard mask layer on the first capping layer:
patterning the first hard mask layer to a first plurality of regions of the substrate;
depositing a second capping layer on the substrate after patterning the first hard mask layer; and
selectively etching the second capping layer from the first plurality of regions of the substrate.

2. The method of claim 1, in which selectively etching comprises maskless selective removal of the second capping layer from the second portion of the semiconductor device.

3. The method of claim 2, in which selectively etching the second capping layer does not substantially modify electronic properties of the semiconductor device.

4. The method of claim 2, in which selectively etching the second capping layer comprises applying a solution to the semiconductor device that etches the second capping layer where the second capping layer is not in contact with the substrate.

5. The method of claim 4, in which applying the solution comprises applying an SC1 solution.

6. The method of claim 4, in which the semiconductor device is a CMOS device, the first plurality of regions of the substrate are PMOS devices.

7. The method of claim 6, in which the first capping layer is aluminum oxide and the second capping layer is lanthanum oxide.

8. The method of claim 2, further comprising depositing a conducting layer after selectively etching the second capping layer.

9. A method of manufacturing a semiconductor device, comprising:
depositing a hard mask layer on a dielectric layer;
patterning the hard mask layer to a first plurality of regions of the dielectric layer;
depositing a first capping layer on the dielectric layer after patterning the hard mask layer;
selectively etching the first capping layer from the first plurality of regions of the dielectric layer;
depositing a second hard mask after selectively etching the first capping layer;
patterning the second hard mask layer to a second plurality of regions of the dielectric layer different than the first plurality of regions of the dielectric layer;
depositing a second capping layer after patterning the second hard mask layer; and
selectively etching the second capping layer from the second plurality of regions of the dielectric layer.

10. The method of claim 9, further comprising annealing the dielectric layer and the first capping layer to form a composite dielectric before selectively etching the first capping layer and after depositing the first capping layer.

11. The method of claim 10, in which the first plurality of regions of the semiconductor device have a different threshold voltage than the second plurality of regions of the semiconductor device.

12. A semiconductor device, comprising:
a first dielectric layer; and
a second dielectric layer contacting the first dielectric layer, in which the semiconductor device has at least a first region and a second region, a composition of the first dielectric layer and the second dielectric layer differing in the first region and the second region.

13. The semiconductor device of claim 12, in which the first region and the second region of the semiconductor device have a different threshold voltage.

14. The semiconductor device of claim 13, in which the first dielectric layer in the first region comprises a high-k dielectric and the second dielectric layer in the first region comprises a composite of high-k dielectric and lanthanum.

15. The semiconductor device of claim 13, in which the first dielectric layer in the second region comprises a composite of high-k dielectric and lanthanum and the second dielectric layer in the second region comprises a high-k dielectric.

16. The semiconductor device of claim 13, further comprising a third region having a different threshold voltage than the first region and the second region.

17. The semiconductor device of claim 16, in which the first dielectric layer and the second dielectric layer in the third region comprise a high-k dielectric.

18. The semiconductor device of claim 13, further comprising a conducting layer on the second dielectric layer.

19. The semiconductor device of claim 18, in which the conducting layer is at least one of a metal and a metal nitride.

20. The semiconductor device of claim 13, in which the semiconductor device is integrated in at least one of a microprocessor, a memory device, and a telecommunications device.
